(19) United States
(12) Patent Application Publication
(10) Pub. No.: US 2014/0375264 A1
(43) Pub. Date: Dec. 25, 2014

(54) SYSTEM AND METHOD FOR DYNAMIC ENERGY LOAD BALANCING FOR ELECTRIC VEHICLE SUPPLY EQUIPMENTS

(71) Applicants: Mahidhar REDDY, Annapolis, MD (US); Harsha KOLLARAMAJALU, Bangalore, IN (US); Roman STANCHAK, Baltimore, MD (US)

(72) Inventors: Mahidhar REDDY, Annapolis, MD (US); Harsha KOLLARAMAJALU, Bangalore, IN (US); Roman STANCHAK, Baltimore, MD (US)

(73) Assignee: SemaConnect, Inc., Annapolis, MD (US)

(21) Appl. No.: 13/921,590

(22) Filed: Jun. 19, 2013

(51) Int. Cl. B60L 11/18; G01R 21/06

(52) U.S. Cl. CPC B60L 11/1838; G01R 21/06
USPC 320/109; 324/103 R

(57) ABSTRACT

A system and method is provided for managing energy load associated with a group of electric vehicle supply equipments (EVSEs). A server may determine a total load associated with the group of EVSEs. In response to a determination that the total load exceeds a predefined load limit, the server may generate an adjust load signal that is communicated to one or more EVSEs in the group of EVSEs.

### TECHNICAL FIELD

The present disclosure relates to the field of electric vehicle supply equipment (EVSE). More specifically, the present disclosure relates to managing energy load associated with a group of electric vehicle supply equipments (EVSEs).

### BACKGROUND

A single electric vehicle supply equipment (EVSE) can draw as much as 30 A (amperes) of current at 240 volts for a peak power of 7.2 kW. A number of such EVSEs are typically installed in parking lots (or other public spaces) where it is not unusual to have hundreds of parking spaces. The peak load for such a parking lot site with an EVSE at each parking space increases rapidly.

Thus, a system is needed which is able to adjust the load associated with a group of EVSEs to meet overall power utilization requirements.

These and other drawbacks exist.

### BRIEF SUMMARY

An electronic system, including hardware, firmware, and methods for adjusting/managing the load associated with a group of EVSEs are described herein.

According to one aspect of the present disclosure, the method may include a plurality of operations. In some implementations, the operations may include receiving, by each EVSE in a group of EVSEs, an amount of power used by the EVSE. In some implementations, the operations may include determining a total load on an electrical power grid based on the received amount of power used by each EVSE. In some implementations, the operations may include determining whether the total load exceeds a predefined load limit. In some implementations, the operations may include generating an adjust load signal in response to a determination that the total load exceeds the predefined load limit. In some implementations, the operations may include communicating the adjust load signal to each EVSE.

### BRIEF DESCRIPTION OF THE DRAWINGS

Aspects of the present disclosure are illustrated by way of example and are not limited by the accompanying figures with like references indicating like elements.

FIG. 1 illustrates an exemplary electric vehicle supply equipment (EVSE), according to various aspects of the invention.

FIG. 2 illustrates components of an enclosure of the EVSE, according to various aspects of the invention.

FIG. 3 illustrates an energy load balancing system, according to various aspects of the invention.

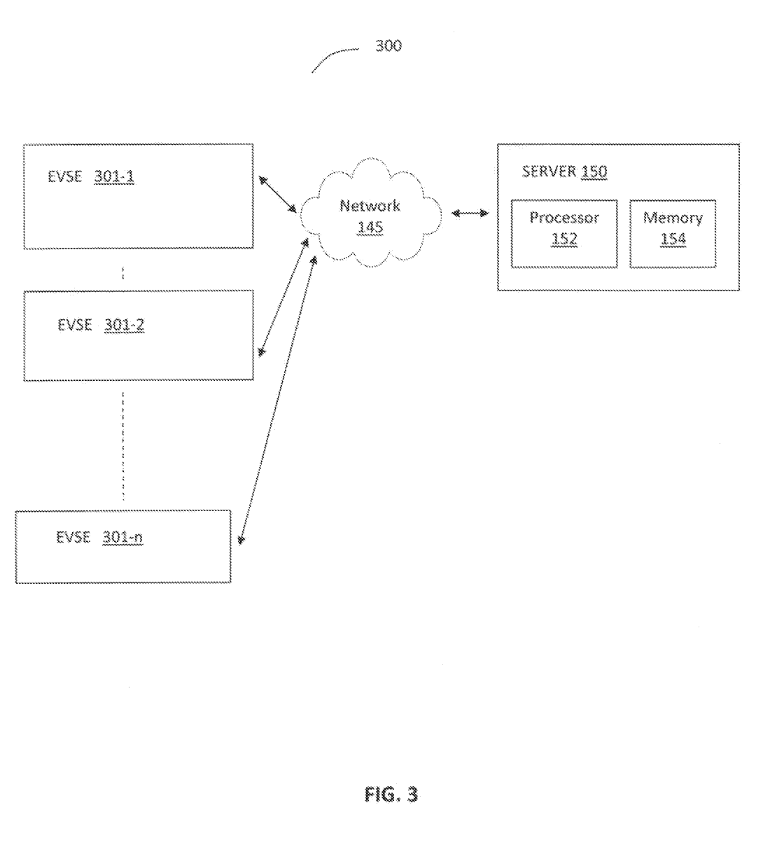

FIG. 4 illustrates a flowchart depicting example operations performed by an EVSE, according to various aspects of the invention.

FIG. 5 illustrates a flowchart depicting example operations performed by a server communicably coupled to a group of EVSE's, according to various aspects of the invention.

### DETAILED DESCRIPTION

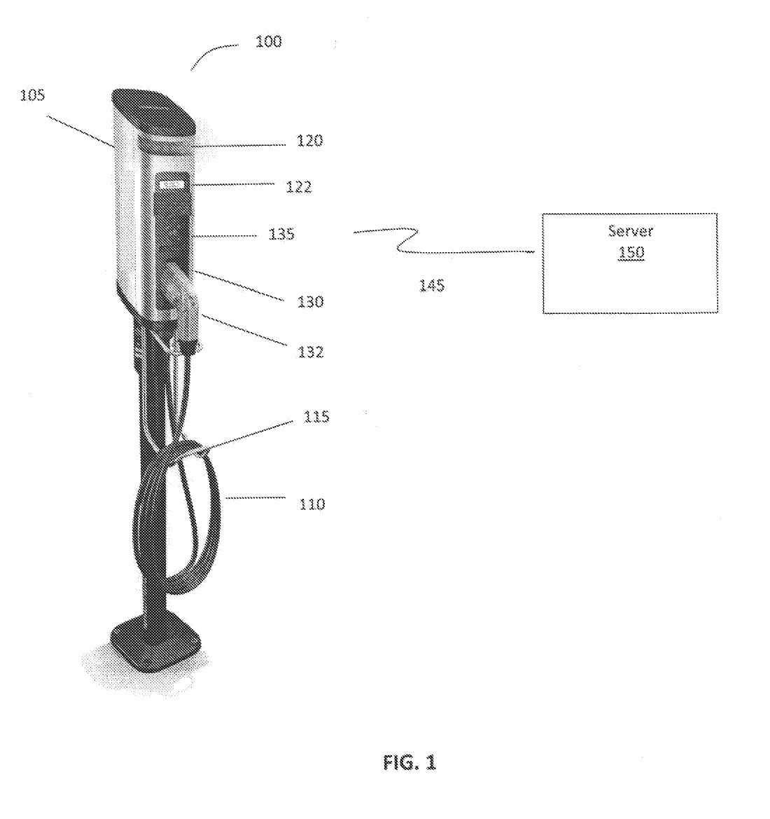

FIG. 1 illustrates an exemplary electric vehicle supply equipment (EVSE) 100, according to various aspects of the invention. EVSE 100 may include an enclosure 105 that houses one or more components of the EVSE 100. Externally, enclosure 105 may include, among other things, LED (light emitting diode) lights 120, a display screen 122 (for example, liquid crystal display or other display), and an opening 130 that accepts a J1772 connector 132 for storage. When connector 132 is plugged into a mating plug on an electric vehicle or plug-in hybrid electric vehicle it is capable of charging the vehicle.

EVSE 100 may include a cable 110 of a particular length that ensures easy charging access over or around the electric vehicle and a bracket 115 for coiling/storing cable 110. In some implementations, the cable length may be 18 feet, though other cable lengths may be used without departing from the scope of the invention. In some implementations, the cable may be used to supply electric energy for charging/recharging of electric vehicles plugged into the EVSE 100.

In some implementations, EVSE 100 may be communicatively coupled to remote server 150 via link or network 145. In some implementations, link or network 145 may include a Local Area Network, a Wide Area Network, a cellular communications network, a Public Switched Telephone Network, a wireless communication network, and/or other network or combination of networks.

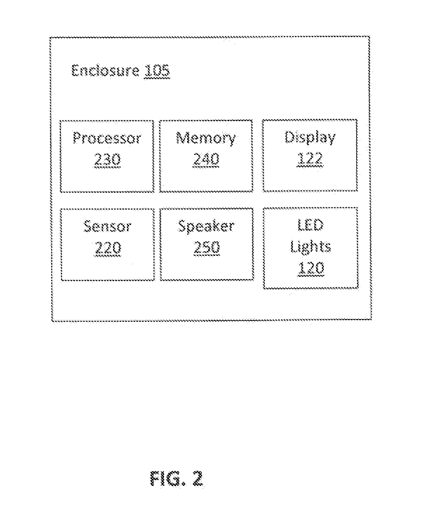

In some implementations, as depicted in FIG. 2, enclosure 105 of EVSE 100 may include a sensor 220, a processor 230, a memory 240, display screen 122, speaker 250, LED lights 120, and/or other components that facilitate the functions of EVSE 100. In some implementations, processor 230 includes one or more processors or microprocessors configured to perform various functions of EVSE 100. In some implementations, memory 240 includes one or more tangible (i.e., non-transitory) computer readable media. Memory 240 may include one or more instructions that when executed by processor 230 configure processor 230 to perform functions of EVSE 100.

In some implementations, sensor 220 may be configured to measure an amount of current drawn by the EVSE 100. In some implementations, the amount of current may include the amount of current drawn by EVSE 100 when an electric vehicle is plugged into the EVSE 100 and/or is being charged by the EVSE 100 (i.e., when the EVSE is in-use). In some implementations, the amount of current may include the amount of current drawn by EVSE 100 when an electric vehicle is not plugged into the EVSE 100 and/or is not being charged by the EVSE 100 (i.e., when the EVSE is not in-use). In some implementations, sensor 220 may be mounted or attached to enclosure 105 and may be coupled to the processor 230.

In some implementations, processor 230 may be configured to determine an amount of power used by the EVSE 100 in response to the sensor measuring the amount of current. In some implementations, sensor 220 may communicate a sensing signal to the processor 230 that provides the measured amount of current to the processor 230. In some implementations, processor 230 may receive the sensing signal and determine the amount of power used by the EVSE 100. In some implementations, processor 230 may communicate the determined amount of power to server 150.

In some implementations, an energy load balancing system 300 may include a plurality of EVSEs 301-1,301-2, . . . , 301-n, each of which is communicatively coupled to server 150. Each EVSE 301-1, 301-2, . . . , or 301-n is similar to EVSE 100 described above with respect to FIGS. 1 and 2. In some implementations, the plurality of EVSEs may be installed at a particular charging site, for example, a parking lot site, or other public commercial or non-commercial sites.

In some implementations. each EVSE 301-1, 301-2, . . . , or 301-n may be configured to measure the amount of current drawn, determine the amount of power used, and/or communicate the associated determined amount of power to remote server 150.

In some implementations, server 150 may include a processor 152, a memory 154, and/or other components that facilitate the functions of server 150. In some implementations, processor 152 includes one or more processors or microprocessors configured to perform various functions of server 150. In some implementations, memory 154 includes one or more tangible (i.e., non-transitory) computer readable media. Memory 154 may include one or more instructions that when executed by processor 152 configure processor 152 to perform functions of server 150. In some implementations, memory 154 may include one or more instructions stored on tangible computer readable media that when executed at a remote device, such as EVSE 301-1, . . . , or 301-n, cause the remote device to facilitate interaction with the server, as described herein.

In some implementations, remote server 150/processor 152 may receive, from each EVSE, the amount of power used by the EVSE. In some implementations, the processor 152 may determine a load on the electrical power grid based on the amount of power used by each EVSE. In some implementations, the load may include a total load determined by combining the load for each EVSE. In some implementations, an EVSE may contribute to the total load when the EVSE is in-use. In some implementations, an EVSE may not contribute significantly to the total load when the EVSE is not in-use (i.e., does not use a significant amount of power in comparison to an EVSE that is in-use).

A charging site, for example, may have 50 EVSEs installed. In some implementations, each EVSE may be capable of supplying 30 A at 208V (i.e., 6.24 kW). If all the EVSEs are in use simultaneously, the total load may be 312 kW (50*6.24). The electricity cost to the charging site operator with the system at peak capacity (i.e., load of 312 kW) can vary from $44/hr to $130/hr based on the time of day.

In some implementations, the energy load balancing system 300 may be configured to adjust the total load on the electrical power grid. In some implementations, processor 152 may determine a total load on the electrical power grid based on the amount of power used by each EVSE within a group of EVSEs. In the example above, the remote server 150 may determine a total load based on the amount of power used by each of the 50 EVSEs (or a sub-group of the 50 EVSEs).

In some implementations, processor 152 may determine whether the total load exceeds or is equal to a predefined limit/threshold. The predefined limit/threshold may define a limit set by the charging site operator on the amount of load that the charging site places on the electrical power grid.

In response to a determination that the total load exceeds or is equal to the predefined limit/threshold, processor 152 may generate an adjust load signal. The processor 152 may communicate the adjust load signal to each EVSE contributing to the total load. For example, one or more EVSEs in the group (whose total load is determined) may not be in-use (i.e., are not used for charging an electric vehicle) while other EVSEs may be in-use (i.e., used for charging the electric vehicle). In some implementations, an EVSE that is used for charging contributes to the total load and thus is provided with the adjust load signal. This is because when an EVSE is not in-use, it draws negligible current, thereby not significantly impacting the total load determination.

In some implementations, processor 152 may identify an EVSE that contributes to the total load based on the amount of power received from the EVSE. In some implementations, processor 152 may communicate the adjust load signal to the identified EVSEs.

In some implementations, the adjust load signal provides an instruction to the EVSE to draw a lower amount of current than the amount of current it was previously drawing to charge the vehicle. By drawing a lower amount of current, each EVSE provided with the adjust load signal, may use a lower amount of power, thereby reducing the total load on the electrical power grid. This would reduce the electricity cost to the charging site operator even when the system is at peak capacity (i.e., all EVSEs are in use).

For example, the total load of 312 kW (for the 50 EVSEs) may need to be adjusted to the predefined limit of 104 kW. To achieve this lower total load, the adjust load signal may instruct each EVSE to draw current at 10 A instead of 30 A.

In some implementations, an administrator may interact with the server 150 via a client device (not otherwise illustrated in the figures). In some implementations, the client device may include a computing/processing device such as a desktop computer, a laptop computer, a network computer, a wireless phone, a personal digital assistant, a tablet computing device, workstation, and/or other computing devices that may be utilized to interact with server 150. In some implementations, the client device may comprise a user interface that may enable the administrator to monitor the power used by a single and/or group of EVSEs and/or the total load associated with the group of EVSEs. In some implementations, the administrator may determine that the total load exceeds or is equal to the predefined limit. In response to the determination, the administrator may prompt the server 150/processor 152 to generate the adjust load signal.

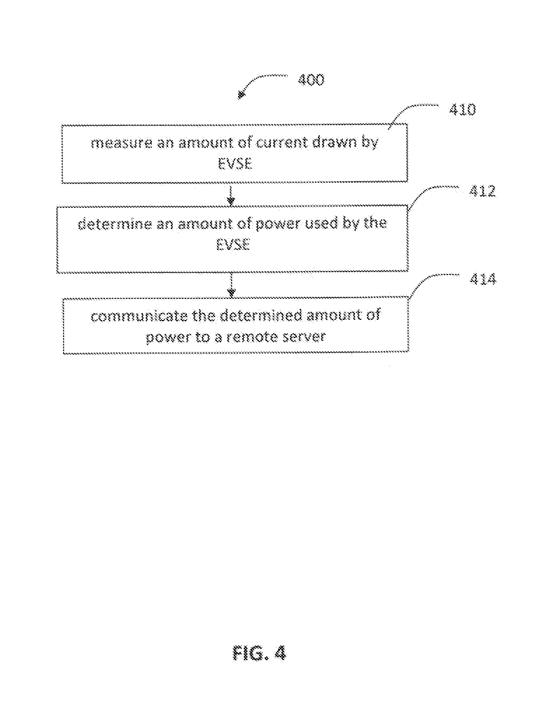

FIG. 4 is a flowchart 400 depicting example operations performed by the EVSE 100, according to various aspects of the invention. In some implementations, the described operations may be accomplished using one or more of the modules/components described herein. In some implementations, various operations may be performed in different sequences. In other implementations, additional operations may be performed along with some or all of the operations shown in FIG. 4. In yet other implementations, one or more operations may be performed simultaneously. In yet other implementations, one or more operations may not be performed. Accordingly, the operations described are exemplary in nature and, as such, should not be viewed as limiting.

In an operation 410, process 400 may measure an amount of current drawn by an EVSE. In an operation 412, process 400 may determine an amount of power used by the EVSE based on the measured amount of current. In an operation 414, process 400 may communicate the determined amount of power to a server.

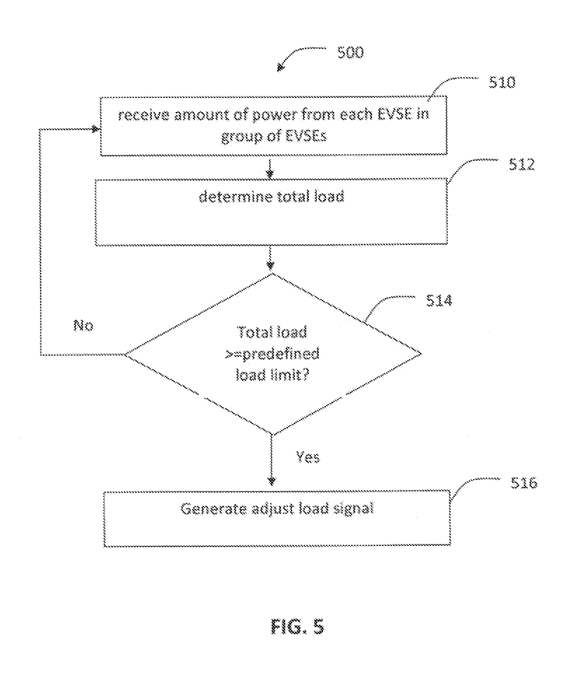

FIG. 5 is a flowchart 500 depicting example operations performed by a server/server processor communicatively coupled to a group of EVSEs, according to various aspects of the invention. In some implementations, the described operations may be accomplished using one or more of the modules/components described herein. In some implementations, various operations may be performed in different sequences. In other implementations, additional operations may be performed along with some or all of the operations shown in FIG. 5. In yet other implementations, one or more operations may be performed simultaneously. In yet other implementations, one or more operations may not be performed. Accordingly, the operations described are exemplary in nature and, as such, should not be viewed as limiting.

In an operation 510, process 500 may receive, from each EVSE in a group of EVSEs, an amount of power used by the EVSE while charging an electric vehicle connected to it. In an operation 512, process 500 may determine a total load on an electrical power grid based on the amount of power used by each EVSE.

In an operation 514, process 500 may determine whether the total load exceeds or is equal to a predefined load limit. In response to a determination that the total load exceeds or is equal to the predefined load limit, process 500 may generate an adjust load signal in an operation 516. In some implementations, the adjust load signal may be communicated to each EVSE contributing to the total load. In some implementations, in response to a determination that the total load does not exceed or is not equal to the predefined load limit, process 500 may continue back to operation 510, where new values for the amount of power may be received from the EVSEs and the process 500 may be repeated.

Implementations of the invention may be made in hardware, firmware, software, or various combinations thereof. The invention may also be implemented as computer-readable instructions stored on a tangible computer-readable storage medium which may be read and executed by one or more processors. A computer-readable storage medium may include various mechanisms for storing information in a form readable by a computing device. For example, a tangible computer-readable storage medium may include optical storage media, flash memory devices, and/or other storage mediums. Further, firmware, software, routines, or instructions may be described in the above disclosure in terms of specific exemplary aspects and implementations of the invention and performing certain actions. However, it will be apparent that such descriptions are merely for convenience, and that such actions may in fact result from computing devices, processors, controllers, or other devices executing firmware, software, routines or instructions.

Other embodiments, uses and advantages of the invention will be apparent to those skilled in the art from consideration of the specification and practice of the invention disclosed herein. The specification should be considered exemplary only, and the scope of the invention is accordingly intended to be limited only by the following claims.

What is claimed is:

1. An electric vehicle supply equipment (EVSE) comprising:
a sensor configured to measure an amount of current drawn by the EVSE;
a processor configured to:
determine an amount of power used by the EVSE; and
communicate the amount of power to a server.

2. The equipment of claim 1, wherein the processor is configured to determine the amount of power used by the EVSE when the EVSE is used for charging an electric vehicle.

3. A system for managing energy load, the system comprising:
a processor configured to:
receive, by each EVSE in a group of EVSEs, an amount of power used by the EVSE;
determine a total load on an electrical power grid based on the received amount of power used by each EVSE;
determine whether the total load exceeds a predefined load limit;
in response to a determination that the total load exceeds the predefined load limit, generate an adjust load signal; and
communicate the adjust load signal to each EVSE.

4. The system of claim 3, wherein processor is further configured to:
identify one or more EVSEs in the group of EVSEs that contribute to the total load; and
communicate the adjust load signal to the identified one or more EVSEs.

5. The system of claim 3, wherein the amount of power used by the EVSE is determined based on an amount of current drawn by the EVSE.

6. The system of claim 3, wherein the amount of power used by the EVSE is determined when the EVSE is used for charging an electric vehicle.

7. The system of claim 5, wherein the adjust load signal comprises an instruction to lower the amount of current drawn by the EVSE.

8. A method for managing energy load, the method comprising:
receiving, by each EVSE in a group of EVSEs, an amount of power used by the EVSE;
determining a total load on an electrical power grid based on the received amount of power used by each EVSE;
determining whether the total load exceeds a predefined load limit;
in response to a determination that the total load exceeds the predefined load limit, generating an adjust load signal; and
communicating the adjust load signal to each EVSE.

9. The method of claim 8, further comprising:
identifying one or more EVSEs in the group of EVSEs that contribute to the total load; and
communicating the adjust load signal to the identified one or more EVSEs.

10. The method of claim 8, wherein the amount of power used by the EVSE is determined based on an amount of current drawn by the EVSE.

11. The method of claim 8, wherein the amount of power used by the EVSE is determined when the EVSE is used for charging an electric vehicle.

12. The method of claim 10, wherein the adjust load signal comprises an instruction to lower the amount of current drawn by the EVSE.
